(19) United States
(12) Patent Application Publication
(10) Pub. No.: US 2026/0014647 A1
(43) Pub. Date: Jan. 15, 2026

(54) HERMETICALLY SEALED ENCLOSURE AND METHOD FOR DESIGNING THE WELD CONNECTION FOR SUCH AN ENCLOSURE

(71) Applicants: Schott AG, Mainz (DE); SCHOTT Primoceler Oy, Tampere (FI)

(72) Inventors: Jens Ulrich Thomas, Mainz (DE); Heidi Lundèn, Tampere (FI); Antti Määttänen, Tampere (FI); Jens Herrmann, Mainz (DE); Axel Ohlinger, Mainz (DE); Angelika Steckermeier, Mainz (DE)

(73) Assignees: Schott AG, Mainz (DE); SCHOTT Primoceler Oy, Tampere (FI)

(21) Appl. No.: 18/881,190

(22) PCT Filed: Jun. 28, 2023
(86) PCT No.: PCT/EP2023/067587

§ 371 Date: Jan. 3, 2025

(30) Foreign Application Priority Data
Jul. 4, 2022 (DE) 10 2022 116 612.0
Jun. 28, 2023 (WO) PCTEP2023067587

(51) Int. Cl. B23K 26/244; B23K 26/324; B23K 26/57; B23K 103/00; H05K 5/06

(52) U.S. Cl. CPC B23K 26/244; B23K 26/324; B23K 26/57; H05K 5/066; B23K 2103/54

(57) ABSTRACT

A base substrate of an enclosure has a functional region and a cover substrate covers the functional region. The base substrate and cover substrate are directly connected together in a hermetically tight manner via at least one laser bonding line so the functional region is hermetically enclosed in the enclosure. For the connection between the substrates a minimum shear force is specified that the laser weld connection is to withstand, a minimum length is determined, by an empirically determined force per laser bonding line length P, for the total length of all bonding lines, and a contact surface width B is selected such that a ratio Aᵢ/A_{w}, formed from a contact surface Aᵢ, at which the base substrate and the cover substrate can touch one another, and a laser bonding surface A_{w} covered by the laser bonding lines with a width w, is in the range from 1 to 10.

### CROSS-REFERENCE TO RELATED APPLICATIONS

This application is a national stage entry under 35 U.S.C. § 371 of International Patent Application No. PCT/EP2023/067587 entitled “HERMETICALLY SEALED ENCLOSURE AND METHOD FOR DESIGNING THE WELD CONNECTION FOR SUCH AN ENCLOSURE” filed Jun. 28, 2023, which is incorporated in its entirety herein by reference. International Patent Application No. PCT/EP2023/067587 claims priority to German Patent Application No. 10 2022 116 612.0 filed on Jul. 4, 2022, which is incorporated in its entirety herein by reference.

### BACKGROUND OF THE INVENTION

### 1. Technical Field of the Invention

The invention relates to a hermetically sealed enclosure comprising a base substrate, which has a functional region, and a cover substrate, which is in contact with the base substrate and covers the functional region, wherein the base substrate and the cover substrate are directly connected hermetically tightly to one another via at least one laser bonding line, and wherein the functional region is hermetically enclosed inside the resulting enclosure. The invention further relates to a method for designing the laser weld connection between the substrates and to the use of such an enclosure.

### 2. Description of the Related Art

Hermetically sealed enclosures are intended, for example, to protect a component or components inside the enclosure against adverse ambient conditions. Application fields for such a hermetically sealed enclosure may, for example, be found in electronics applications in order to protect sensitive electronic component parts, and may also be found in optics applications in order to encapsulate optical components. Further applications are found particularly in the field of medical implants, microfluidic chips, augmented reality and sensor technology for mobility (for example pressure sensors).

Particularly in optical applications, transparent materials such as glass are desirable for the enclosure. But also in electronics applications in which wireless communication or wireless charging is desired, glass materials are advantageous s over conventional metal housings, for example consisting of titanium, since they do not shield the radiation respectively being used.

One example of such a hermetically sealed enclosure is known from EP 3 812 352 A1. The enclosure comprises at least a base substrate and a cover substrate, which form the housing while enclosing a functional region in the interior. The cover substrate and the base substrate, which are selected for example from a glass material, are connected to one another by the elaboration of laser bonding lines.

A method for producing a transparent part to protect an optical component by using a laser method in order to generate laser bonding lines is also known from the European patent specification EP 3 012 059 B1.

In these known laser methods, two substrates are respectively placed on one another and a spacing or gap possibly still existing between the substrates is sealed by the elaboration of a laser weld so that the connection between the two substrates is hermetically tight.

In particular when used as an implant, the enclosures formed must satisfy stringent mechanical requirements. One measure of the mechanical strength of the connection of two housing parts is the resistance against shear forces. The more stable the connection is, the higher are the shear forces that the connection can withstand without coming apart. When connecting two substrates, the shear force resistance is dependent on the size of a contact area over which the two substrates are in contact with one another.

In order to ensure a sufficient shear force resistance, the known hermetic enclosures therefore have comparatively large wall thicknesses, which may be several mm. Besides increasing the wall thickness, the parts to be connected may also be configured so that they have a form-fit. This, however, likewise requires a great deal of installation space and is expensive, particularly in the case of component parts consisting of glass and the like. This makes particularly compact embodiment of the hermetic enclosures more difficult.

An object of the invention may therefore be regarded as to provide a hermetic enclosure which has particularly thin walls and, at the same time, satisfies the mechanical requirements. A further object of the invention may be regarded as to provide a method for designing a laser weld between constituent parts of an enclosure, with which a particularly compact and at the same time sufficiently robust enclosure may be obtained, based on a specified mechanical requirement.

### SUMMARY OF THE INVENTION

A method for designing a laser weld between a base substrate and a cover substrate of an enclosure is proposed. The enclosure to be formed has at least the base substrate, with a functional region, and the cover substrate. The cover substrate is in contact with the base substrate and covers the functional region. The base substrate and the cover substrate are directly connected hermetically tightly to one another via at least one laser bonding line so that the functional region is hermetically enclosed inside the resulting enclosure. A minimum shear force resistance Fₘᵢₙ, which the laser weld is intended to withstand, is in this case specified for the connection between the cover substrate and the base substrate, and the sum of the lengths Les of all laser bonding lines is selected to be greater than a required minimum length Lₘᵢₙ of the length of all laser bonding lines, Lₘᵢₙ=Fₘᵢₙ/P being determined by dividing the specified minimum shear force Fₘᵢₙ by an empirically determined force per unit laser bonding line length P, and
a contact area width B, measured in the plane of the front face of the base substrate, which faces toward the cover substrate, as the shortest route between the functional region and the exterior of the enclosure, being selected so that a ratio J=Aᵢ/A_{w} formed from a contact area Aᵢ, on which the base substrate and the cover substrate can touch, and a laser bonding area A_{w} spanned by the laser bonding lines with a width w on the front face of the base substrate, which faces toward the cover substrate, lying in the range of from 1 to 10.

Preferably, a number N of closed paths of laser bonding lines with width w and a distance H between the midpoints of two neighboring laser bonding lines of at least the width w are arranged around the functional region, the number N being determined as the smallest number N for which the total length L_{ges} of all laser bonding lines, formed from the number N multiplied by the length of a contour line that delimits the functional region, is greater than the minimum length Lₘᵢₙ.

In the context of this application, a contact area is the cross section of the contiguous faces of the two substrates to be brought in contact. The touching contact area means a subarea of the contact area, in which the spacing of the two substrates from one another is so small that it is no longer optically measurable. In particular, a distance between the surfaces of the neighboring substrates in the region of the touching contact area is less than 250 nm. In general, the contact area is greater than or equal to the touching contact area.

In other words, two substrates are initially arranged on one another, i.e. for example stacked on one another, the force of gravity pressing the upper-lying substrate, typically the first substrate, onto the second substrate. The orientation above or below is merely intended descriptively, since the substrates may of course occupy any orientation in space, and arrangement next to one another s also not to depart from the scope of protection. The two substrates are typically arranged bearing on one another with a larger side of their extent.

If the two substrates are formed in an absolutely planar fashion, i.e. they have no depressions, elevations or curvatures at all, which in this idealized form is only theoretically achievable, the first and second substrate would be in surface-wide touching contact with one another. The two substrates would thus touch at all points of the surfaces that are oriented toward one another. This is therefore not achievable in general and in constructional reality. Rather, even if only to a very small extent, substrates are nevertheless cambered, inclined, curved, or provided with depressions or elevations, so that complete touching contact is only ever achieved in absolute exceptional cases.

The functional region enclosed by the enclosure may, in particular, be a cavity which is adapted to receive a functional element. The cavity has a bottom face and side walls, which are provided by the base substrate, and has a top face, which is provided by the cover substrate. The thickness of the side walls corresponds in this embodiment to the contact area width.

In other examples of the enclosure, the functional region may be a functionalized region of the base substrate. Such functionalization may, for example, take place by applying a coating and/or by surface structuring.

The functional region is hermetically tightly sealed by the weld connection. Here, in particular, hermetically tight means an enclosure which has a helium leak rate of less than 1·10⁻⁸ mbar l/sec and preferably lies in the range of from 1·10⁻¹⁰ mbar l/sec to 1·10⁻⁹ mbar l/sec.

The weld connection is elaborated by introducing at least one laser bonding line, or laser weld line. The weld connection is in this case preferably elaborated by using an ultrashort-pulse laser. Typical pulse widths lie in the range of from 100 fs to 100 ps. A method for elaborating such a weld connection with one or more laser weld lines is known, for example, from EP 3 012 059 B1.

The laser weld line has a height HL in a direction perpendicular to its connection plane. The connection plane is the direction in which the neighboring or successive beam points are set. Typically, the laser welding is carried out from a plan-view perspective, that is to say the substrate stack lies for example on a surface—such as a table—and the laser is shot from above at least through the uppermost substrate layer—or through a plurality of substrate layers—to the position of the beam focus. The height HL is thus measured in the direction of the laser beam, while the width w of the laser weld line is measured perpendicularly to the direction of the laser beam.

The width w of the region modified by the laser beam varies along the depth T of the processed region, i.e. along the laser beam direction. The indications given in the context of this application relating to the width w of the laser weld line are referenced to the plane of the contact area between the substrates connected by the laser weld line. In this plane thus defined, the width w means the region inside which material modifications have been induced by the laser treatment. Such material modifications due to the laser treatment result from the heating above the glass transition temperature T_{g} and/or the melting temperature of the materials involved and subsequent recooling. By this laser treatment, the two substrates are materially bonded to one another in this processed region, without additional connecting materials being involved. In the case of optically transparent materials, the material modification induced by the laser treatment may for example be detected by measuring a change in refractive index relative to the untreated material. For this purpose, for example, a cross-section polish may be examined with a light microscope. In particular, a modification of the refractive index by more than 1×10⁻⁵ may be used as a marker for the material modification and correspondingly for the determination of the width w. A micrograph of such a cross-section polish may be seen in FIG. 10 and will be described in more detail below.

A multiplicity of materials may be connected to one another by the laser welding method, in which case at least the substrate that faces in the direction of the laser source should be at least partially transparent for the laser used.

The laser weld lines or laser bonding lines generated are arranged around the functional region so that, in a contact plane which corresponds to the front face of the base substrate, which faces toward the cover substrate, a closed region enclosing the functional region is formed by the laser bonding area. In the case of a cuboid enclosure, one or more laser bonding lines extending in a straight line may then be arranged on each of the four sides delimiting the functional region, in which case the laser bonding lines may overlap in the four corners. The one or more laser bonding lines may, in particular, each extend parallel to the side walls. It is also possible to arrange one or more closed laser bonding line(s) for example parallel to a contour line of the functional region.

For the hermetic enclosing of the functional region, at least one laser bonding line must be placed continuously around the functional region. This criterion may, however, also be fulfilled by a plurality of individually inscribed laser bonding lines which overlap at points of intersection while forming a closed path around the functional region. One laser bonding line arranged around the functional region then corresponds to each of these closed paths in the context of the method, in the case of precisely one such path the number being N=1 and, for example, in the case of precisely two closed paths the number being N=2. Insofar as one single such closed laser bonding line is sufficient to exceed the determined minimum length Lₘᵢₙ in order to satisfy the specified minimum shear force Fₘᵢₙ, the number N of laser bonding lines which are placed around the functional region may be selected as N=1. In this case, there are no laser bonding lines arranged neighboring one another in the context of the method.

Preferably, a plurality of laser bonding lines in the form of a plurality of such closed paths are introduced, neighboring laser bonding lines which extend inside the region defined by the respective contact area width preferably being arranged parallel to one another. Laser bonding lines which are separated from one another by the functional region are not in this case regarded as neighboring.

Preferably, a distance H between the midpoints of two neighboring laser bonding lines with the width w is selected in the range of from 1 w to 5 w, preferably in the range of from 1.01 w to 2.5 w and particularly preferably in the range of from 1.05 w to 2 w. This avoids the laser bonding lines overlapping, apart from possibly existing intersections of different laser bonding lines.

The effect achieved by providing a distance of at least the width of the laser bonding lines between two neighboring laser bonding lines, which in particular extend parallel to one another, is that the material of the substrates is processed only once, apart from intersections of laser bonding lines, for example at the four corners around a rectangular functional region.

On the other hand, the upper limit provided for the distance achieves a particularly compact embodiment of the laser bonding area. The contact area width B may therefore be selected to be particularly small but nevertheless offer sufficient space for the formation of the laser bonding lines.

Preferably, the contact area width B is selected in the range of from 100 μm to 1000 μm. The precise selection of the contact area width B is dependent on various criteria such as the material of the base substrate, the material of the cover substrate, the dimensions of the enclosure and/or the nature of the functional region. If a cavity is provided as the functional region, the contact area width B dictates the thickness of the side walls of the functional region. The contact area width is in this case selected to be preferably at least so large that the mechanical stability of the side wall is sufficiently great.

Preferably, the contact area width B is selected to be greater than 200 μm, particularly preferably greater than 300 μm, more preferably greater than 400 μm and most preferably greater than 500 μm.

The larger the contact area width B is selected to be, however, the larger the enclosure becomes in relation to the enclosed functional region. Correspondingly, it is preferred to select the contact area width B to be less than 750 μm, particularly preferably less than 500 μm and more particularly less than 400 μm. The minimum contact area width is limited by the width w of a laser bonding line and is therefore preferably selected to be greater than 30 μm, particularly preferably greater than 50 μm and more particularly preferably greater than 100 μm.

The width w of the laser bonding lines is preferably selected in the range of from 20 μm to 75 μm, particularly preferably in the range of from 30 μm to 60 μm. For example, a width w of 50 μm is selected. This range is optimally selected in order to be able to introduce sufficient energy for the welding of the two substrates via the laser. It is in this case particularly advantageous for the width w to be substantially constant over the entirety of the laser bonding lines. Correspondingly, it is preferred for the width w of all laser bonding lines to vary by at most 30%, particularly preferably at most 20%, most preferably at most 10% over the total length L_{ges} of the laser bonding lines. Since the width w is dependent on the location of the focal point of the laser in relation to the contact plane, the use of a laser processing method with precise control of the separation of the laser focus from the contact plane is preferred. A suitable method is known, for example, from EP 3 012 059 B1.

For a maximally compact enclosure, the fill factor J=Aᵢ/A_{w} formed from a contact area Aᵢ, on which the base substrate and the cover substrate can touch, and a laser bonding area A_{w} spanned by the at least one laser bonding line with a width w should be selected to be as small as possible. Correspondingly, it is particularly preferred to select the fill factor J in the range of from 1 to 5, most preferably in the range of from 1 to 2.

According to the proposed method, provision is made to select the total length of the laser bonding lines introduced, and therefore the laser bonding area A_{w}, to be precisely so large that there t is a specified resistance of the weld connection against exerted shear forces. The term shear forces in this case means in particular forces which act on the two substrates perpendicularly to their connection plane and which, without a connection between the substrates, would lead to a mutual displacement of the substrates.

The Inventors have established that the shear force resistance of the weld connection increases linearly with the total length of the nonoverlapping laser bonding lines. For the nonoverlapping criterion, small overlaps, for example at points of intersection of laser bonding lines extending at a right angle to one another and arranged around a rectangular functional region, may be neglected because of the small area of these intersections. Correspondingly, when specifying the minimum shear force Fₘᵢₙ, against which the weld connection is intended to be resistant, and an empirically determined constant P for the increase in force per unit length, the required minimum length of the sum of the laser bonding lines may be ascertained via the relationship

$${L}_{min} = {F}_{min} / P .$$

The total length L_{ges} of the laser bonding lines introduced may, particularly in the case of laser bonding lines extending parallel around the functional region, be determined as an integer multiple of the length of a contour line around the functional region. The small increase of the actual length of the circumferential laser bonding lines due to the fact that the laser bonding lines are elaborated as nonoverlapping may again be neglected because of the small width of the laser bonding lines. Small further bonding line portions, which may occur when manufacturing a multiplicity of enclosures by processing a wafer and subsequently singulating the enclosures, may also be neglected because of their short length.

The constant P is specific to the materials of the substrates to be connected and the selected width of the laser bonding line, and may easily be determined empirically by producing a plurality of test specimens, for example a batch of 30, in which a first substrate consisting of a cover substrate material is connected to a second substrate consisting of a base substrate material by laser bonding lines, the total length Les of the laser bonding lines in the test specimens being selected equally. The shear force resistance of the test specimens is subsequently determined by applying an increasing shear force to the connection of the first and second substrates, determining the force at which the connection is destroyed, and evaluating a failure probability distribution.

The minimum shear force Fₘᵢₙ, against which the weld connection is intended to be resistant, is preferably specified to be no greater than necessary, so that the weld connection itself and therefore the enclosure as a whole may be embodied as compactly as possible. Preferably, the specification is contingent on the mechanical requirements for the enclosure. One criterion may, in particular, be that the minimum shear force is referenced to other force resistances of the substrates. Preferably, for this purpose the minimum shear force Fₘᵢₙ is specified by producing a plurality of test specimens, n which a first substrate consisting of a cover substrate material is connected to a second substrate consisting of a base substrate material by laser bonding lines so that they are designed for a minimum shear force Fₘᵢₙ, and when this minimum shear force Emin is applied more than 50%, preferably more than 75%, particularly preferably more than 90%, most preferably 95% of test specimens do not break along the contact area by failure of the weld connection but break at other places, in particular at an edge of one or more of the substrates.

For determining the failure rate, in a similar way to that for ascertaining the empirical constant P, a plurality of test specimens of the same type may be produced, for example a batch of 30, in which two substrates have been welded to one another by introducing laser bonding lines. The total length of the laser bonding lines is in this case selected according to the shear force Fₘᵢₙ to be tested. A shear force is then applied increasingly to the test specimens. The position at which a test specimen mechanically fails may be ascertained easily by visual assessment of the test specimen. If the weld connection fails, the individual substrates are separated again but are substantially without any further damage. If the number of test specimens which do not break along the contact area by failure of the weld connection lies in the intended range, for example more than 75%, the tested shear force Emin has been selected correctly. Otherwise, the experiment is repeated for a higher or lower shear force to be tested, depending on the result.

The designing of the weld connection may be followed by steps for producing the enclosure. These steps may, in particular, comprise providing the substrates and optionally cleaning the surfaces of the substrates, placing the substrates on one another, a functional element optionally being introduced into a functional region, and introducing the laser bonding lines.

During the production, provision may in particular be made to generate a multiplicity of enclosures in one run. For this purpose, large wafers are initially provided instead of substrates already tailored to the final size of the enclosure, and are placed on one another layerwise and connected to one another by the laser welding. The individual enclosures are subsequently singulated by cutting the wafer stack that has been formed. In such a procedure, provision may be made that the laser bonding lines introduced are inscribed along a grid pattern, a functional region respectively being enclosed by four laser bonding lines that form a rectangle.

A further aspect of the invention is the provision of a hermetically sealed enclosure. The proposed hermetically sealed enclosure comprises a base substrate, which has a functional region, and a cover substrate, which is in contact with the base substrate and covers the functional region, the base substrate and the cover substrate being directly connected hermetically tightly to one another via at least one laser bonding line, and the functional region being hermetically enclosed inside the resulting enclosure. Provision is further made that a ratio J=Aᵢ/A_{w} formed from a contact area Aᵢ, on which the base substrate and the cover substrate can touch, and a laser bonding area A_{w} spanned by the at least one laser bonding line with a width w on the front face of the base substrate, which faces toward the cover substrate, lies in the range of from 1 to 10, a contact area width B, measured in the plane of the front face of the base substrate, which faces toward the cover substrate, as the shortest route between the functional region and the exterior of the enclosure, lying in the range of 100 μm to 1000 μm.

The proposed enclosure is particularly compact, since the contact area width B is embodied so that the laser bonding area A_{w} fills as great as possible a part of the total contact area Aᵢ.

In the case of hermetic enclosures known from the prior art, which are obtained by laser welding of substrates, it has been assumed that a substantial part of the mechanical stability is provided by a contact area that is as large as possible and the laser bonding area is substantially required in order to ensure the hermetic enclosing of the functional region. Because of the laser bonding area A_{w}, which is usually small in comparison with the total contact area Aᵢ, only a small contribution to the mechanical stability, in particular to the resistance against shear forces, has previously been assumed with regard to the laser bonding area A_{w} itself.

Furthermore, it has surprisingly been established that maximization of the shear force resistance of the weld connection of the two substrates is not advantageous, since in this case the enclosure breaks uncontrolledly at other places under the action of large mechanical forces. Further lengthening of the weld seam thus does not contribute to an improvement of the overall strength of the enclosure. In addition, the weld seams which are in this way “unnecessary” require a larger contact area and thus increase the “footprint” of the enclosure. Accordingly, it is preferred to specify not only a lower limit but also an upper limit for the shear force resistance.

Preferably, for this purpose the laser bonding area A_{w} spanned by the at least one laser bonding line is selected so that the connection between the cover substrate and the base substrate has a failure shear force in the range of from 10 N to 1000 N, preferably from 50 N to 500 N, particularly preferably in the range of from 100 N to 400 N.

Preferably, the total length L_{ges} of the laser bonding lines of the enclosure is determined by one of the design methods described herein. It is particularly preferred that the specified minimum shear force Fₘᵢₙ, which the laser weld is intended to withstand, corresponds to this failure shear force in the range of from 10 N to 1000 N.

Since the enclosure may be obtained by using one of the described methods, features described in the scope of one of the methods also apply for the enclosure, and vice versa features disclosed in the scope of the enclosure also apply for the methods.

Preferably, the welding is elaborated with a plurality of laser bonding lines, the laser bonding lines having a width w, and a distance H between the midpoints of two neighboring laser bonding lines being selected in the range of from 1 w to 5 w, preferably in the range of from 1.01 w to 2.5 w and particularly preferably in the range of from 1.05 w to 1.5 w.

The width w of the laser bonding lines preferably lies in the range of from 20 μm to 75 μm, particularly preferably from 30 μm to 60 μm. For example, the laser bonding lines are 50 μm wide. It is in this case particularly advantageous for the width w to be substantially constant over the entirety of the laser bonding lines. Correspondingly, it is preferred for the width w of all laser bonding lines to vary by at most 30%, particularly preferably at most 20%, most preferably at most 10% over the total length L_{ges} of the laser bonding lines.

The enclosure is preferably configured as compactly as possible. This is achieved by the part of the contact area not occupied by the laser bonding area being kept as small as possible, and as a consequence thereof the contact area width B also being made as small as possible. For this purpose, provision is preferably made that the front face of the base substrate, which faces toward the cover substrate and corresponds to the contact area Aᵢ, is covered to at least 20% with laser bonding lines and J therefore lies in the range of from 1 to 5. Particularly preferably, at least half of the contact area Aᵢ is covered with laser bonding lines, in which case J lies in the range of from 1 to 2.

The cover substrate is preferably formed as a transparent thin-film substrate, the cover a substrate having thickness of less than 200 μm, preferably less than 170 μm, particularly preferably less than 125 μm, and preferably having a thickness of more than 10 μm, particularly preferably more than 20 μm. In this way, the dimension of the enclosure may also be embodied particularly compactly in the stack direction of the substrates.

The cover substrate may in this case already be provided in the form of a thin-film substrate and welded to the base substrate. As an alternative thereto, a substrate with a greater thickness may be thinned by material erosion after having been connected to the base substrate.

The cover substrate and the base substrate adjoin one another directly on the contact area Aᵢ, so that the connection in the laser bonding area A_{w} spanned by the at least one laser bonding line is free from extraneous materials, in particular free from connecting materials such as adhesive, a glass frit or an absorbing layer. Since no extraneous materials have been used during the closing of the enclosure, contaminations of the functional region, for example by constituents of an adhesive, are avoided.

The functional region may be formed as a cavity. Such a cavity is preferably adapted to receive a functional element, so that one or more functional elements may be received in the cavity of such an enclosure. The cavity has a bottom face and side walls, which are provided by the base substrate, and has a top face, which is provided by the cover substrate. The thickness of the side walls corresponds in this embodiment to the contact area width.

The base substrate may have a flat bottom substrate, which forms the bottom face of a functional region configured as a cavity, and an intermediate substrate, which forms the side walls of the cavity, with a front face facing toward the cover substrate. The bottom substrate and the intermediate substrate are preferably connected hermetically tightly to one another via at least one laser bonding line. For the design of this weld connection, the method described herein may in particular be applied similarly and the weld connection may be elaborated in a similar way to the connection described herein between the cover substrate and the base substrate.

As an alternative thereto or in addition, the base substrate may be formed a functional region in the form of a depression with a bottom face and side walls, which form a cavity together with the cover substrate as a top face. Such depressions may, for example, be formed by grinding or etching.

In other examples of the enclosure, the functional region may be a functionalized region of the base substrate. Such functionalization may, for example, take place by applying a coating and/or by surface structuring.

The cover substrate and/or the base substrate preferably consist of a glass, a glass ceramic, silicon, sapphire or a combination of the aforementioned materials. In particular, borosilicate glasses are suitable as glass materials.

The invention also relates to the use of the proposed enclosure as an enclosure of a sensor unit and/or of a medical implant. In these applications, the hermetic tightness and the achievable compact dimensions of the enclosure are particularly advantageous. In the case of small wall thicknesses and the selection of a contact area width of for example 500 μm, the enclosure is only insubstantially larger than a functional element received therein.

A sensor unit and/or medical implant comprising one of the enclosures described herein is furthermore correspondingly. The enclosure preferably has a cavity, which encloses a functional element of the sensor unit and/or of the medical implant.

An example of an enclosure comprises a bottom substrate and an intermediate substrate, which together form a base substrate, as well as a cover substrate. All substrates consist of a borosilicate glass, which is available for example under the name BOROFLOAT 33. The bottom substrate and the intermediate substrate have a thickness of 1.1 mm, and the cover substrate has thickness of 500 μm. A length and width of the substrates is in each case 5 mm. By selecting the contact area width B of 500 μm, a cavity having side walls and a top wall with a thickness of 500 μm is provided.

Example of the determination of the empirical parameter P:

Specimens were produced, in which two substrates were placed on one another, each consisting of a floated borosilicate flat glass available under the name BOROFLOAT® 33 with a length and width of 5 mm and a thickness of 1.1 mm. In order to verify the assumption that the shear force is linearly on the total length of the laser bonding lines, laser bonding lines with a total length L_{ges} of 20 mm were inscribed in a first type 1. Laser bonding lines with a total length Les of 40 mm were inscribed in a second type 2, and laser bonding lines with a total length Les of 60 mm were inscribed in a third type 3. The laser bonding lines may in principle be introduced in any desired geometry. In the present example, one half of the bonding line length was in each case inscribed along a first direction, and the other half of the bonding line length was inscribed along a second direction perpendicular thereto, so that a “+” shape was formed. The overlap of the laser bonding lines at the center of this cross shape may be neglected because of its small area.

Of each of the three types, 30 specimens were produced and the shear force at which the connection between the two substrates failed was respectively determined. For this purpose, an apparatus was used in which two plates lying on one another can be displaced with a defined force relative to one another, i.e. sheared. A depression, the shape and depth of which correspond to the dimensions of the substrates to within a small tolerance, is arranged in each of the plates. Accordingly, the side walls of the depressions each bear closely on the side faces of the respective substrates. In order to determine the shear force at which a connection between the two substrates of one of the specimens fails, a specimen was placed between the two plates and the two plates were displaced relative to one another at a rate of 1.5 mm/min, the force being measured. When the connection fails, the specimen no longer exerts a resistance against the displacement, which is identified via an abrupt reduction of the measured force. The shear force at which the connection failed is then the highest force ascertained during the displacement or shearing of the two plates.

The measurement is repeated for all specimens, the shear force at which the connection between the two substrates of a specimen fails being recorded in each case. The measurement results for the cumulative probability KP are plotted in a log-log representation in FIG. 6.

By fitting the parameters of a distribution function p (F) for the cumulative failure probability at a shear force of F, a failure shear force Fᵥ at which the corresponding specimen type fails may then be determined. The distribution function p(F) is given by

$$p ( F ) = 100 \% \cdot ( 1 - {e}^{- \frac{{F}^{z}}{{F}_{V}}} ) ,$$

where the parameter z indicates the width of the distribution function and may likewise be ascertained by the parameter fit.

For a confidence interval of 95%, the following results are obtained for the failure shear force Fᵥ for the three specimen types, and these are also represented in FIG. 7 as a function of the total length L_{ges} of the laser bonding lines:

$${F}_{v} = 107.9 ( 101.8 … 114.3 ) N \qquad Type 1 :$$

$${F}_{v} = 144.1 ( 139.6 … 148.8 ) N \qquad Type 2 :$$

$${F}_{v} = 219.6 ( 206.6 … 233.6 ) N \qquad Type 3 :$$

By fitting an affine function, it is readily apparent that the specimens without laser welding, i.e. for a length of the laser bonding lines of 0, already have a nonzero failure shear force of approximately 45 N. This basic contribution to the shear force resistance is attributed to the adhesion forces over the optical interface area A_{c}. It may furthermore be seen that the shear force resistance increases by about 2.8 N for each mm of laser bonding line.

For the material pairing used both specimen types 1 to 3, an empirical constant P of 2.8 N/mm is correspondingly ascertained.

Since a linear relationship is involved here, for an empirical determination of the constant it is sufficient to carry out this measurement on a single specimen type for the material pairing to be studied.

It is to be understood that the features mentioned above and those yet to be explained below may be used not only in the combination respectively indicated but also in other combinations or individually, without departing from the scope of the present invention.

### BRIEF DESCRIPTION OF THE DRAWINGS

Preferred elaborations and embodiments of the invention are represented in the drawings and will be explained in more detail in the following description, reference signs which are the same referring to structural parts or elements which are the same or similar or functionally equivalent.

In a schematic form

FIG. 1 shows a perspective view of substrates connected by a laser bonding line,

FIG. 2 shows a plan view of a hermetic enclosure,

FIG. 3 shows a sectional view of the hermetic enclosure from the side,

FIG. 4 shows a section through laser bonding lines along the welding direction,

FIG. 5 shows a section through laser bonding lines perpendicularly to the welding direction,

FIG. 6 shows a diagram of the failure probability of laser-welded test specimens in the shear test for three different total lengths of the laser bonding lines as a function of the shear force exerted,

FIG. 7 shows a diagram of the characteristic failure force of the laser-welded test specimens as a function of the total length of the laser bonding lines,

FIG. 8 shows a diagram of the empirical constant determined for the bonding strength per unit length,

FIG. 9 shows a micrograph of a cross-section polish of two substrates connected to one another by laser bonding lines,

FIG. 10 shows three examples of fracture patterns for the failure of the weld connection when the failure shear force is exceeded, and

FIG. 11 shows three examples of fracture patterns in which one or both substrates are fractured by the action of force without prior failure of the weld connection.

### DETAILED DESCRIPTION OF THE INVENTION

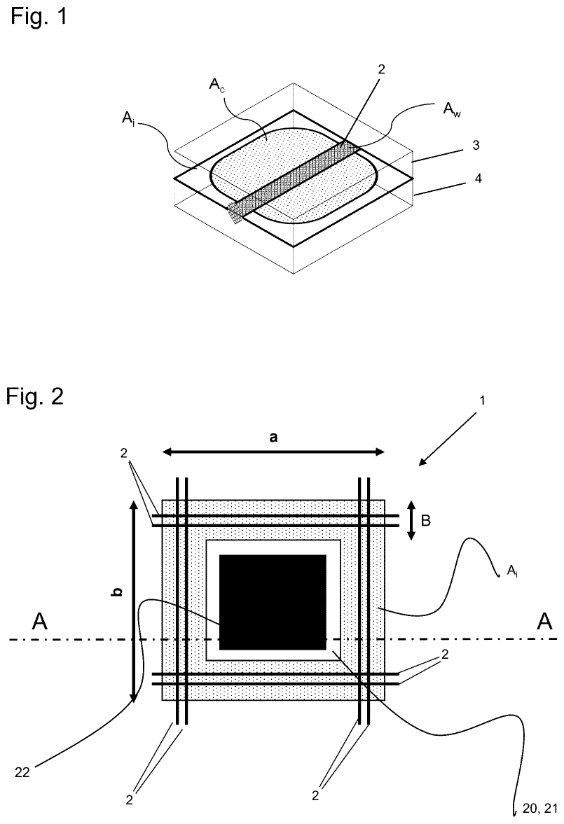

FIG. 1 represents a perspective view of two substrates 3, 4 connected by a laser bonding line 2. A first substrate 3 is in this case placed on a second substrate 4 so that the two substrates 3, 4 touch directly. The area on which the two substrates 3, 4 touch is referred to as the contact area Aᵢ.

If the surfaces of the two substrates 3, 4 are smooth, the surfaces placed on one another have a spacing from one another which can no longer be optically determined. This is usually the case for a spacing of less than about 250 nm. With such small spacings, adhesion forces already occur between the two substrates 3, 4 during the placement. These adhesion forces occur in a region which is referred to as the touching contact area A_{c}. The touching contact area A_{c} is less than the total contact area Aᵢ.

For the hermetically tight connection of the two substrates 3, 4 in the region of the touching contact area A_{c}, laser welding is carried out by introducing a laser bonding line 2. Along the laser bonding line 2, material is melted with an ultrashort-pulse laser and recooled, so that the two substrates 3, 4 are connected to one another if they adjoin one another very tightly as in the region of the touching contact area A_{c}. In a laser bonding area A_{w} generated by the laser welding, the two substrates 3, 4 are materially bonded to one another so that there is no longer any spacing between the substrates 3, 4. At about 20 μm to 75 μm, the width of the laser bonding lines 2 is thin, so that in the surface-wide connection of the substrates 3, 4 represented as an example in FIG. 1 only a very small part of the touching contact area A_{c}, or of the contact area Aᵢ, is additionally welded by laser treatment.

Surprisingly, it has been found that the contribution to the shear force resistance of the connection of the two substrates 3, 4 by the laser bonding area A_{w}, despite the very small area compared with the total contact area Aᵢ and the touching contact area A_{c} in the example represented in FIG. 1, is very much greater than the contribution of the adhesion forces in the region of the touching contact area A_{c}. The laser bonding area A_{w} may accordingly be used not only to hermetically tightly seal a gap existing between the two substrates, but also to increase the resistance of the connection against exerted shear forces.

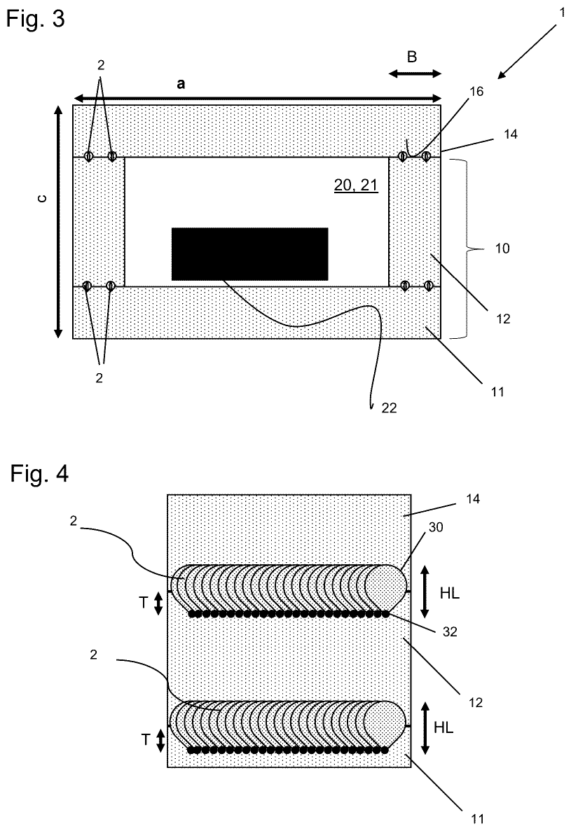

FIG. 2 shows a plan view of an exemplary embodiment of a hermetic enclosure 1. The enclosure has a length a, a width b and a height c (cf. FIG. 3). A functional region 20 in the form of a hollow space or cavity 21, into which a functional element 22 is hermetically tightly encapsulated, for example a sensor or a transponder, is formed in the enclosure 1.

Typical measurements of an enclosure are a=5 mm, b=5 mm, c=2.5 mm, although larger-area and flatter (for example a=10 mm, 10=5 mm, c=0.9 mm) or more compact (a=3 mm, b=4 mm, c=2 mm) ones are also possible.

In order to form the enclosure 1, a cover substrate 14 is placed onto a base substrate 10 (cf. FIG. 3) and touches the base substrate 10 on the contact area Aᵢ. The contact area Aᵢ corresponds to a front face 16 of the base substrate 10, cf. FIG. 3.

Via a plurality of laser bonding lines 2, the cover substrate 14 is connected hermetically tightly to the base substrate 10. The laser bonding lines 2 extend parallel to the side walls of the cavity 21, the cavity 21 being rectangular in the example represented, and correspondingly having four side walls. In the example, two bonding lines 2 in each case extend parallel to one of the side walls of the cavity, the thickness of the side walls corresponding to a contact area width B. Only those bonding lines 2 that are not separated from one another by the functional region 20, or the cavity 21, are regarded as neighboring one another. The laser bonding lines 2 in this example form two closed rectangular paths around the functional region 20.

The enclosure represented in FIG. 2 was obtained from a wafer stack in which a wafer for the base substrate 10 and a wafer for the cover substrate 14 were placed on one another and connected to one another. A wafer stack which comprises a multiplicity of enclosures 1 connected to one another was thereby obtained. The laser bonding lines 2 were respectively elaborated over the entire width, or length, of the wafer stack. The individual enclosure 1, as is represented in FIG. 2, was obtained by singulating the multiplicity of enclosures.

FIG. 3 shows a sectional view of the hermetic enclosure 1 of FIG. 2 from the side along the section line marked by A-A in FIG. 2.

It may be seen in the sectional representation of FIG. 3 that the base substrate 10 in this exemplary embodiment consists of a bottom substrate 11 and an intermediate substrate 12. A connection of the bottom substrate 11 and the intermediate substrate 12 was elaborated hermetically tightly in a similar way to the connection between the cover substrate 14 and the base substrate 10, or the intermediate substrate 11, via a plurality of laser bonding lines 2.

The side walls of the resulting cavity 21 are formed here by the intermediate substrate 12, and the bottom of the cavity 21 is formed by the bottom substrate 11. In the example represented, the functional element 22 is arranged inside the cavity 21 on the bottom substrate 11.

FIG. 4 shows a section through laser bonding lines 2 along the welding direction. The welding direction is the direction along which the laser beam was guided over the substrates 11, 12, 14 to be connected, the individual pulses locally overlapping multiply so that a weld seam is created by accumulation of heat above the focal points 32. The cross section of the seam is pyriform and is referred to as a weld pear 30. The weld pear 30 represents the region of the substrates 11, 12, 14 that has been processed by the respective laser pulse in such a way that the material was heated above the glass transition temperature T_{g}, or the melting temperature, and the respectively neighboring substrates 11, 12, 14 are able to be materially bonded. The scan speed is selected in conjunction with the pulse repetition rate of the ultrashort-pulse laser so that a continuous laser bonding region is created in the region of the laser bonding line 2.

The laser beam is focused so that a focal point 32 is placed at a distance T from the connection plane between the two respective substrates 11, 12, 14. Starting from the focal point 32, the weld pear 30 is then formed with a height HL by the energy transferred onto the respective substrate 11, 12, 14 by the laser pulse.

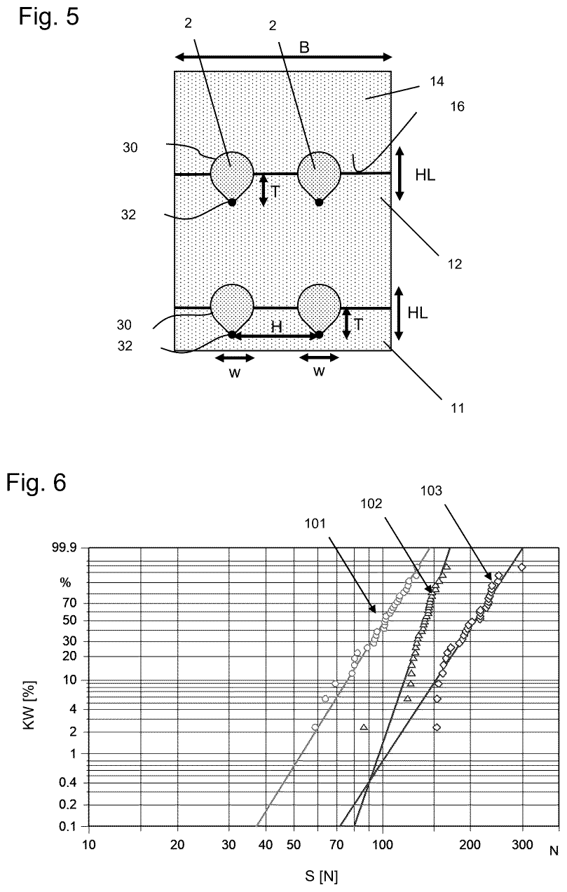

FIG. 5 shows a section through laser bonding lines 2 perpendicularly to the welding direction. It may be seen in this sectional representation that the respective laser bonding lines 2 have a width w in relation to the connection plane between the substrates 11, 12, 14 respectively to be connected, i.e. in this case once between the bottom substrate 11 and the intermediate substrate 12 and a further time between the intermediate substrate 12 and the cover substrate 14. Since the width of the weld pears 30 varies along the height HL of the weld pears 30, the width w of the laser bonding lines 2 may correspondingly be adjusted by selection of the depth T of the focal point 32 in relation to the respective connection plane. A distance H respectively between two neighboring laser bonding lines 2, in each case measured from midpoint to midpoint, is preferably selected so that the laser bonding lines 2 do not overlap. Accordingly, the distance H is greater than or equal to the width w. It is furthermore desirable to embody the enclosure 1 as compactly as possible, and accordingly to select the contact area width B, which corresponds here to the width of the side wall of the cavity 21, cf. FIG. 3, to be as small as possible. Accordingly, a distance between two laser bonding lines 2 is preferably selected to be at most five times the width w.

FIG. 6 shows a log-log representation of the cumulative failure probability of laser-welded test specimens in the shear test for three different total lengths of the laser bonding lines as a function of the shear force exerted in N. A first curve 101 shows the cumulative failure probability for 30 test specimens with a laser bonding line length of in total 20 mm, a second curve 102 shows the cumulative failure probability for 30 test specimens with a laser bonding line length of in total 40 mm, and a third curve 103 shows the cumulative failure probability for 30 test specimens with a laser bonding line length of in total 60 mm.

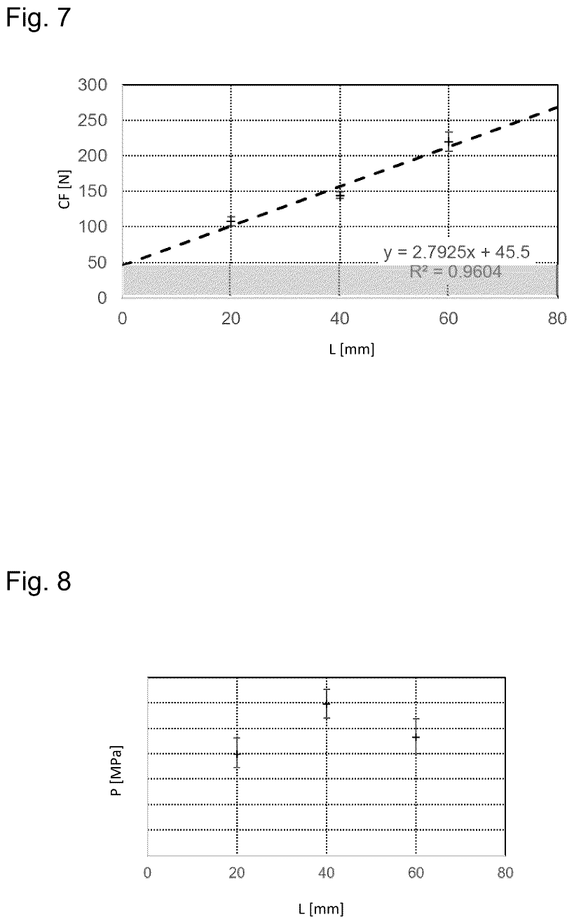

FIG. 7 shows a diagram of the characteristic failure force of the laser-welded test specimens as a function of the total length of the laser bonding lines. A fitted affine function may be used to determine the empirical constant P. The slope of the function corresponds to the constant P. The y axis intercept corresponds to the adhesion force provided by a touching contact area A_{c}, cf. FIG. 1.

FIG. 8 shows a diagram of the empirical constant P determined for the bonding strength per unit length for the three curves 101, 102, 103, cf. FIG. 6. It may be seen that, within the scope of the error tolerance, the values obtained for the constant p are independent of the laser bonding line length of the respective test specimens.

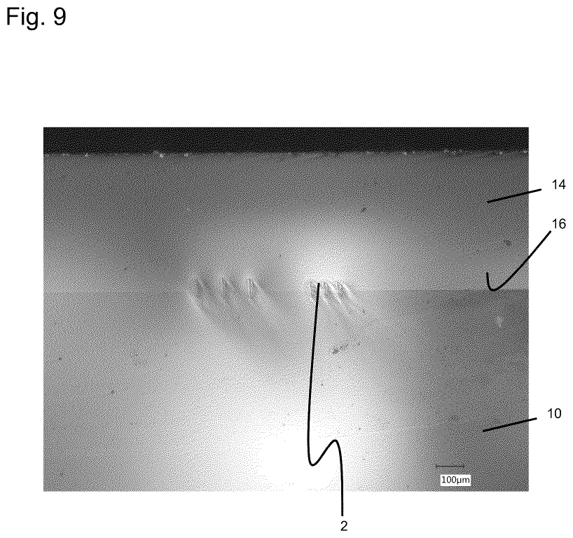

FIG. 9 shows a micrograph of a cross-section polish of two substrates 10, 14 connected to one another by laser bonding lines 2 with reference to the example of substrates 10, 14 consisting of a borosilicate glass. The laser bonding lines 2 may be seen clearly because of the refractive index changes that occur during the heating and recooling.

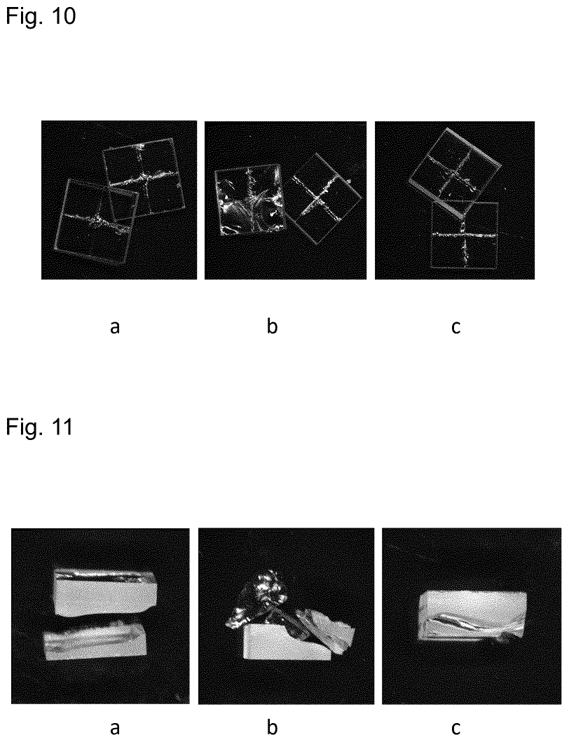

FIG. 10 shows three examples a, b and c of fracture patterns for the failure of the weld connection between two substrates when the failure shear force is exceeded. It may be seen clearly here that the two substrates have been separated from one another substantially without further damage along the weld seams, or laser bonding lines.

FIG. 11 shows three examples a, b, c of fracture patterns in which one or both substrates are fractured by the action of force without prior failure of the weld connection. It may in each case be seen clearly that the fracture lines do not extend along the original surfaces of the substrates here, but rather the respective substrates themselves have been destroyed. Parts of the respective substrates are chipped.

Although the present invention has been described with the aid of preferred exemplary embodiments, it is not restricted thereto but may be modified in a variety of ways.

### LIST OF REFERENCE SIGNS

Aᵢ contact area
A_{c} touching contact area
A_{w} laser bonding area
1 enclosure
2 laser bonding line
3 first substrate
4 second substrate
10 base substrate
11 bottom substrate
12 intermediate substrate
14 cover substrate
16 front face
20 functional region
21 cavity
22 functional element
30 weld pear
32 focal point
A section line
a length of enclosure
b width of enclosure
C height of enclosure
B contact area width
HL height of laser bonding line
T depth of laser bonding line
W width of laser bonding line
H distance between two laser bonding lines
101 first curve
102 second curve
103 third curve
5 KW cumulative failure probability
S shear force
p empirical constant
Fᵥ failure shear force
L laser bonding line length

1-17. (canceled)

18. A method for designing a laser weld between a base substrate and a cover substrate of an enclosure, wherein the base substrate has a functional region and the cover substrate, which is in contact with the base substrate, covers the functional region, the method comprising:
directly connecting the base substrate and the cover substrate to one another hermetically tightly via at least one laser bonding line so that the functional region is hermetically enclosed inside the resulting enclosure, wherein a minimum shear force Fₘᵢₙ, which the laser weld is intended to withstand, is specified for the connection between the cover substrate and the base substrate, and in that a sum of lengths L_{ges} of all laser bonding lines is selected to be greater than a required minimum length Lₘᵢₙ of the length of all laser bonding lines, Lₘᵢₙ being determined by dividing the specified minimum shear force Fₘᵢₙ by an empirically determined force per unit laser bonding line length P so Lₘᵢₙ=Fₘᵢₙ/P, and in that a contact area width B, measured in a plane of a front face of the base substrate, which faces toward the cover substrate, as a shortest route between the functional region and an exterior of the enclosure, is selected so that a ratio J=Aᵢ/A_{w} formed from a contact area Aᵢ, on which the base substrate and the cover substrate can touch, and a laser bonding area A_{w} spanned by the at least one laser bonding line with a width w on the front face of the base substrate, which faces toward the cover substrate, lies in a range of from 1 to 10.

19. The method of claim 18, wherein the at least one laser bonding line comprises a plurality of laser bonding lines and a number N of closed paths of laser bonding lines with width w and a distance H between midpoints of two neighboring laser bonding lines of at least the width w are arranged around the functional region, the number N being determined as a smallest number N for which the total length L_{ges} of all laser bonding lines, formed from the number N multiplied by a length of a contour line that delimits the functional region, is greater than the minimum length Lₘᵢₙ.

20. The method of claim 19, wherein the distance H between the midpoints of two neighboring laser bonding lines with the width w is selected in a range of from 1 w to 5 w.

21. The method of claim 20, wherein the distance His in the range of from 1.01 w to 2.5 w.

22. The method of claim 18, wherein the contact area width B is selected in a range of from 100 to 1000 μm.

23. The method of claim 18, wherein the width w of the at least one laser bonding line is selected in a range of from 20 μm to 75 μm.

24. The method of claim 23, wherein the width w of the at least one laser bonding line is selected in the range of from 30 μm to 60 μm.

25. The method of claim 18, wherein the force per unit laser bonding line length P is determined empirically by producing a plurality of test specimens, in which a first substrate consisting of a cover substrate material is connected to a second substrate consisting of a base substrate material by laser bonding lines, the total length L_{ges} of the laser bonding lines in the test specimens being selected equally, a shear force resistance of the test specimens being determined by applying an increasing shear force to the connection of the first substrate and the second substrate, determining a force at which the connection is destroyed, and evaluating a failure probability distribution.

26. The method of claim 18, wherein the minimum shear force Fₘᵢₙ is specified in such a way that, when producing a plurality of test specimens, in which a first substrate consisting of a cover substrate material is connected to a second substrate consisting of a base substrate material by laser bonding lines so that they are designed for a minimum shear force Fₘᵢₙ, and when this minimum shear force Fₘᵢₙ is applied more than 50% of the test specimens do not break along a contact area by failure of the weld connection but break at an edge of one or more of the substrates.

27. A hermetically sealed enclosure, comprising:
a base substrate having a functional region; and
a cover substrate which is in contact with the base substrate and covers the functional region, wherein the base substrate and the cover substrate are directly connected hermetically tightly to one another via at least one laser bonding line, and wherein the functional region is hermetically enclosed inside the resulting enclosure, wherein a ratio J=Aᵢ/A_{w} formed from a contact area Aᵢ, on which the base substrate and the cover substrate can touch, and a laser bonding area A_{w} spanned by the at least one laser bonding line with a width w on a surface of an interface between the base substrate and the cover substrate lies in a range of from 1 to 10, and a contact area width B, measured in a plane of a front face of the base substrate, which faces toward the cover substrate, as a shortest route between the functional region and an exterior of the enclosure, lying in a range of 100 μm to 1000 μm.

28. The enclosure of claim 27, wherein the area A_{w} spanned by the at least one laser bonding line is selected so that the connection between the cover substrate and the base substrate has a failure shear force in a range of from 10 N to 1000 N.

29. The enclosure of claim 28, wherein the failure shear force is in the range of from 50 N to 500 N.

30. The enclosure of claim 27, wherein a total length L_{ges} of all laser bonding lines is selected by a design method as claimed in claim 18.

31. The enclosure of claim 27, wherein the at least one laser bonding line comprises a plurality of laser bonding lines, the laser bonding lines having a width w, and a distance H between midpoints of two neighboring laser bonding lines being selected in a range of from 1 w to 5 w.

32. The enclosure of claim 27, wherein the cover substrate is formed as a transparent thin-film substrate having a thickness of less than 200 μm.

33. The enclosure of claim 27, wherein the cover substrate and the base substrate adjoin one another directly on the contact area Aᵢ, so that the connection in the laser bonding area A_{w} spanned by the at least one laser bonding line is free from extraneous materials comprising connecting materials or an absorbing layer.

34. The enclosure of claim 27, wherein the base substrate has a flat bottom substrate, which forms a bottom face of the functional region configured as a cavity, and an intermediate substrate, which forms side walls of the cavity, with a front face facing toward the cover substrate, and in that the bottom substrate and the intermediate substrate are connected hermetically tightly to one another via at least one laser bonding line, or in that the functional region in the form of a depression with a bottom face and side walls, which forms a cavity together with the cover substrate as a top face, is formed in the base substrate.

35. The enclosure of claim 27, wherein the cover substrate and/or the base substrate consists of glass, glass ceramic, silicon, sapphire or a combination of the aforementioned materials.

36. The enclosure of claim 27, characterized in that the width w of the at least one laser bonding line lies in a range of from 20 μm to 75 μm and/or the at least one laser bonding line comprises a plurality of laser bonding lines and the width w of all laser bonding lines varies by at most 30% over a total length L_{ges} of the laser bonding lines.

37. A sensor unit and/or a medical implant, comprising:
an enclosure comprising:
a base substrate having a functional region; and
a cover substrate which is in contact with the base substrate and covers the functional region, wherein the base substrate and the cover substrate are directly connected hermetically tightly to one another via at least one laser bonding line, and wherein the functional region is hermetically enclosed inside the resulting enclosure, wherein a ratio J=Aᵢ/A_{w} formed from a contact area Aᵢ, on which the base substrate and the cover substrate can touch, and a laser bonding area A_{w} spanned by the at least one laser bonding line with a width w on a surface of an interface between the base substrate and the cover substrate lies in a range of from 1 to 10, and a contact area width B, measured in a plane of a front face of the base substrate, which faces toward the cover substrate, as a shortest route between the functional region and an exterior of the enclosure, lying in a range of 100 μm to 1000 μm.
